(19) United States
(12) Patent Application Publication
(10) Pub. No.: US 2026/0305199 A1
(43) Pub. Date: Oct. 1, 2026

(54) PRECURSORS FOR LOW DIELECTRIC FILM DEPOSITION

(71) Applicant: Lam Research Corporation, Fremont, CA (US)

(72) Inventors: Douglas Walter Agnew, Portland, OR (US); Konner Eric Kurt Holden, Sherwood, OR (US); Ravi Kumar, Beaverton, OR (US); Jennifer Leigh Petraglia, Lake Oswego, OR (US); Dennis M. Hausmann, Lake Oswego, OR (US); David Joseph Mandia, Lake Oswego, OR (US); Kyle Jordan Blakeney, Milpitas, CA (US); Matthew Bertram Edward Griffiths, Campbell, CA (US)

(21) Appl. No.: 19/490,152

(22) PCT Filed: Jun. 12, 2024
(86) PCT No.: PCT/US2024/033522

§ 371 Date: Dec. 4, 2025

Related U.S. Application Data
(60) Provisional application No. 63/507,970, filed on Jun. 13, 2023.

(51) Int. Cl. H10P 14/692; C23C 16/40; C23C 16/44; C23C 16/455; C23C 16/52; H10P 14/60; H10W 20/00

(52) U.S. Cl. CPC H10P 14/69215; C23C 16/401; C23C 16/4408; C23C 16/45536; C23C 16/45544; C23C 16/45553; C23C 16/52; H10P 14/6336; H10P 14/6339; H10P 14/6682; H10W 20/071

(57) ABSTRACT

Plasma enhanced atomic layer deposition methods and apparatuses for depositing low dielectric constant doped silicon oxide films from fluorocarbosilane, fluorosilane or carbosilane precursors which are a single source of the desired dopants are provided. Conformal deposition may be achieved by utilization of silicon precursors having at least one direct silicon-fluorine bond or fluorine connected to silicon through a linker. The methods may also include fluoro carboaminosilanes or fluoroaminosilanes.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

As dimensions in integrated circuits become ever smaller and as circuit speeds become faster, the demands made on the materials that they are formed from grow ever more stringent. Examples include interlayer dielectrics (ILD) and inter-metal dielectric layers (IMD) that may be used to separate different levels of inter-circuit wiring. To minimize the incidence of mutually induced signals between two such levels, it is necessary to make the IMD or ILD as thin as possible and its dielectric constant as low as possible.

In practice, considerations such as planarity and via plug integrity limit the maximum IMD thickness. Therefore, attempts have been made to find alternative dielectrics to silicon dioxide. Since silicon dioxide already has a low dielectric constant (about 4), the choice of materials is very limited.

A promising candidate to replace silicon dioxide as an IMD is fluorinated silicon glass, (known as FSG or SiOF). FSG films are known to have a dielectric constant of 3.2 to 3.9, depending upon the fluorine concentration. Chemical vapor deposition (CVD) or plasma enhanced chemical vapor deposition (PECVD) has been utilized where no complex topography is involved. However, it can be challenging to deposit such films by CVD or PECVD for some applications, such as through-silicon vias having aspect ratios of greater than 10:1. A plasma-enhanced atomic layer deposition process to deposit FSG films which is useful for higher aspect ratios and higher conformality requirements thus remains desirable.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Deposition methods and apparatuses for depositing doped silicon oxide films from fluorocarbosilane, fluorosilane or carbosilane precursors are provided. The methods may be plasma enhanced atomic layer deposition methods for depositing low dielectric constant doped silicon oxide films. Advantageously, precursors are selected to serve as a single source of the desired set of dopants which may be fluorine, carbon, nitrogen or a combination thereof. Conformal deposition may be achieved by utilization of silicon precursors having at least one direct silicon-fluorine bond or fluorine connected to silicon through a linker. The methods may also include fluoro carboaminosilanes or fluoroaminosilanes.

Accordingly, in a first aspect, the present disclosure encompasses a method for deposition of a doped silicon oxide film. In some embodiments, the method includes a) providing a substrate in a process chamber; b) exposing the substrate to a silicon-containing precursor, wherein the silicon-containing precursor is a fluorocarbosilane, fluorosilane, or a carbosilane, and wherein the silicon-containing precursor includes one to five silicon atoms; c) purging the process chamber with an inert gas; d) exposing the substrate to a plasma of an oxidant or a plasma of a reducing agent; e) purging the process chamber with an inert gas; and f) depositing a doped silicon oxide film, where the doped silicon oxide film is a film doped with N, C, F or a combination thereof; where the method includes one or more cycles of operations a)-f); and where the doped silicon oxide film has a dielectric constant of about 3.9 or less.

In some embodiments, the fluorosilane is a fluoro carboaminosilane precursor or a fluoroaminosilane precursor.

In some embodiments, the fluorosilane has a direct silicon-fluorine bond, fluorine connected to silicon through a linker, or a direct silicon-fluorine bond and fluorine connected to silicon through a linker.

In some embodiments, the linker is alkyl, aryl, amino or heterocyclyl.

In some embodiments, the silicon-containing precursor is a halogenated precursor including at least one fluorine.

In some embodiments, the halogenated precursor also includes one or more halogens selected from the group consisting of chlorine, bromine, iodine and combinations thereof.

In some embodiments, the carbosilane is a fluorocarboaminosilane precursor, a fluorocarbosilane precursor, or a carboaminosilane precursor.

In some embodiments, the carbosilane is octamethylcyclotetrasiloxane, tetravinylmethylcyclotetrasiloxane, tetramethylcyclotetrasiloxane, tetraethylorthosilicate, tetramethylorthosilicate, pentamethylcyclopentasiloxane or hexamethylcyclotrisiloxane.

In some embodiments, the doped silicon oxide film is additionally doped with B, P, Sb, Ga or a combination thereof.

In some embodiments, the oxidant is oxygen, water, nitrous oxide, carbon dioxide, ozone, hydrogen peroxide or a combination thereof.

In some embodiments, exposing the substrate to the oxidant includes flowing the oxidant in an inert gas comprising argon, nitrogen, neon, krypton, helium or a combination thereof.

In some embodiments, purging is performed by delivering an inert gas of argon, nitrogen, neon, krypton, helium or a combination thereof.

In a second aspect, the present disclosure encompasses a method for deposition of a doped silicon oxide film. In some embodiments, the method includes a) providing a substrate in a process chamber; b) exposing the substrate to a silicon-containing precursor, where the silicon-containing precursor includes at least one Si—F bond, at least one Si—C bond, or at least one Si—C bond and at least one Si—F bond and where the silicon-containing precursor includes one to five silicon atoms; c) purging the process chamber with an inert gas; d) exposing the substrate to a plasma of an oxidant or a plasma of a reducing agent; e) purging the process chamber with an inert gas; and f) depositing a doped silicon oxide film, where the doped silicon oxide film comprises a film doped with C, F or a combination thereof; where the method includes one or more cycles of operations a)-f); and where the doped silicon oxide film has a dielectric constant of about 3.9 or less.

In some embodiments, the silicon-containing precursor has a structure of formula (I)

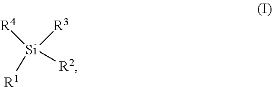

where R¹, R², R³ and R⁴ are each independently H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, heterocyclyl, aromatic, aromatic-carbonyl, aromatic-carbonyloxy, aromatic-oxy, aromatic-oxycarbonyl, heteroaromatic, heteroaromatic-oxy, amino, amido, hydrazino, azido, hydroxyl, halo, silyl, silyloxy, alkoxy, cyanato, isocyanato, isothiocyanato, thiocyanato, cyano, or isocyano; and where R¹ and R² may be linked to form a ring, or wherein R¹, R² and R³ may be linked to form a ring; and with the proviso that at least one of R¹, R², R³ and R⁴ is or includes fluorine, or that at least one of R¹, R², R³ and R⁴ includes carbon, or that at least one of R¹, R², R³ and R⁴ is or includes fluorine and at least one of R¹, R², R³ and R⁴ includes carbon.

In some embodiments, at least one of RI, R², R³ and R⁴ is haloaliphatic, haloalkyl, haloheteroaliphatic, halocyclic or haloaromatic.

In some embodiments, the silicon-containing precursor has a structure of formula (II)

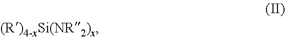

where x is 1, 2, 3, or 4; each R′ is independently H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, heterocyclyl, aromatic, aromatic-carbonyl, aromatic-carbonyloxy, aromatic-oxy, aromatic-oxycarbonyl, heteroaromatic, heteroaromatic-oxy, amino, amido, hydrazino, azido, hydroxyl, halo, silyl, silyloxy, alkoxy, cyanato, isocyanato, isothiocyanato, thiocyanato, cyano, or isocyano; and each R″ is independently H, halo, aliphatic, heteroaliphatic, aromatic, heteroaromatic, alkylsilyl or amino; or optionally wherein two R″ can be taken together, with a nitrogen atom to which each is attached, to form an optionally substituted heterocyclyl; and
with the proviso that at least one of R′ and R″ is or includes fluorine, or that at least one of R′ and R″ includes carbon, or that at least one of R and R is or includes fluorine and at least one of R and R″ includes carbon.

In some embodiments, at least one of R′ and R″ is or includes fluorine.

In some embodiments, at least one of R′ and R″ is haloaliphatic, haloalkyl, haloheteroaliphatic, halocyclic or haloaromatic.

In some embodiments, each R′ is independently hydrogen, —F, —CF₃, —CH₂CF₃, —CH₂CHF₂, —CH₂CH₂F, —CHFCF₃, —CHFCHF₂, —CHFCH₂F, —C(F)═CF₂, —CF₂CF₃, —CF₂CH₃, —CF₂CHF₂, or —CF₂CH₂F.

In some embodiments, two R″ can be taken together, with a nitrogen atom to which each is attached, to form an optionally substituted heterocyclyl of the formula (IIa) or (IIb)

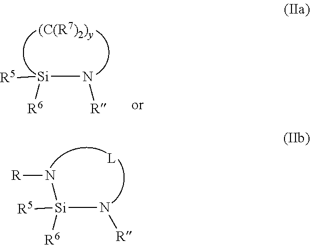

where each R″ is independently H, halo, aliphatic, heteroaliphatic, aromatic, heteroaromatic, alkylsilyl or amino; R⁵, R⁶ and R⁷ are each independently H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, halo, silyl, silyloxy, cyanato, isocyanato, cyano, or isocyano; L is ethylene, 1,2-cyclohexanediyl, benzyl-2-yl, o-phenylene or 1,8-naphthylene; and y is an integer of 3 or 4.

In some embodiments, the silicon-containing precursor has a structure of formula (III)

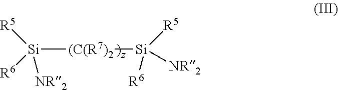

where each R″ is independently H, halo, aliphatic, heteroaliphatic, aromatic, heteroaromatic, alkylsilyl or amino; R⁵, R⁶ and R⁷ are each independently H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, heterocyclyl, amino, amido, hydrazino, azido, hydroxyl, halo, silyl, silyloxy, alkoxy, cyanato, isocyanato, isothiocyanato, thiocyanato, cyano, or isocyano; and z is an integer of 0 to 3; and with the proviso that at least one of R″, R⁵, R⁶ and R⁷ is or includes fluorine, or that at least one of R″, R⁵, R⁶ and R⁷ includes carbon, or that at least one of R″, R⁵, R⁶ and R⁷ is or includes fluorine and at least one of R″, R⁵, R⁶ and R⁷ includes carbon.

In some embodiments, the silicon-containing precursor is a halosilane, a carbosilane or a halocarbosilane.

In some embodiments, the doped silicon oxide is a film further doped with N, B, P, Sb, Ga or a combination thereof.

In some embodiments, the oxidant is oxygen, water, nitrous oxide, carbon dioxide, ozone, hydrogen peroxide or a combination thereof.

In some embodiments, exposing the substrate to the oxidant includes flowing the oxidant in an inert gas of argon, nitrogen, neon, helium, krypton or a combination thereof.

In some embodiments, purging is performed by delivering an inert gas of argon, nitrogen, neon, helium, krypton or a combination thereof.

In a third aspect, the present disclosure encompasses an apparatus for deposition of a doped silicon oxide film. In some embodiments, the apparatus includes one or more process chambers including a substrate support; a plasma generator; one or more process gas sources connected with the process chamber and flow-control hardware; and a controller having at least one processor and a memory, where
the at least one processor and the memory are communicatively connected with one another, the at least one processor is at least operatively connected with the flow-control hardware, and the memory stores computer-executable instructions for controlling the at least one processor to at least control the flow-control hardware to perform the disclosed methods.

These and other aspects are described further below with reference to the drawings.

### BRIEF DESCRIPTION OF THE DRAWINGS

FIG. 1 presents a process flow diagram for a non-limiting method for plasma-enhanced atomic layer deposition of a low dielectric constant doped silicon oxide film in accordance with certain disclosed embodiments.

FIG. 2 presents a schematic diagram of an example process chamber for performing the methods in accordance with certain disclosed embodiments.

FIG. 3 presents a schematic diagram of an example process tool for performing the methods in accordance with certain disclosed embodiments.

FIG. 4 presents a schematic diagram of an example multi-station process tool for performing the methods in accordance with certain disclosed embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

### Definitions

The term “aspect ratio” generally represents a ratio between a depth of a feature of a substrate and an average width of the feature. The term “high aspect ratio (HAR)” generally represents features with depth:width ratios of higher than 1:1.

The term “atomic layer deposition” (ALD) generally represents a process in which a film is formed on a substrate in one or more individual layers by sequentially adsorbing a precursor to a substrate and then chemically transforming the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth”, “deposition”, and variants thereof also can be used to refer to film formation.

The terms “atomic layer deposition cycle” and “ALD cycle” generally represent a single cycle of adsorbing a chemical precursor on a substrate surface and then chemically transforming the adsorbed chemical precursor to form a film layer on the substrate.

The term “dielectric film” generally represents a layer of an insulating material that can be polarized by an applied electric field. Example dielectric films comprise silicon oxide (SiO₂), silicon nitride (Si₃N₄), silicon oxynitride (Si₃N₄₍₁₋ₓ₎O₆ₓ), silicon carbide (SiC), silicon oxycarbide (SiO₂₍₁₋ₓ₎Cₓ), aluminum nitride (AlN), aluminum oxide (Al₂O₃), tin oxides (e.g. SnO, SnO₂), gallium nitride (GaN), boron nitride (BN) and gallium arsenide (GaAs) films.

The term “doping” and variants thereof generally represent the introduction of an impurity into a material for the purpose of modifying one or more physical properties of the material. The term “dopant” generally represents a chemical species introduced into another material as an impurity in a doping process.

The term “flow control hardware” generally represents components configured to place one or more chemical sources in fluid connection with a processing chamber. Flow control hardware can comprise one or more mass flow controllers and/or valves, for example. Example chemical sources include dielectric film precursor sources, halogen-containing precursor sources, reactant gas sources, and inert gas sources.

The term “forming a gas mixture” generally represents either of or both of mixing a plurality of gases before introducing the plurality of gases into the processing chamber, or mixing a plurality of gases in the processing chamber.

The term “inert gas” generally represents a gas phase material that does not react with other chemicals in a processing chamber during substrate processing. Example inert gases include helium (He), neon (Ne), argon (Ar), krypton (Kr), and xenon (Xe), as well as nitrogen (N₂) in some processes.

The term “plasma” generally represents a gas comprising cations, free radicals and free electrons. The term “in-situ plasma” generally represents a plasma formed at a processing station in a processing chamber. The term “remote plasma” generally represents a plasma formed at a location away from a processing station in a processing chamber.

The term “plasma generator” generally represents a combination of components that can be used to form a plasma. Example components include a radiofrequency power source, an impedance matching network, and one or more electrodes.

The term “precursor” generally represents a chemical species that adsorbs to a substrate surface in an ALD process. The precursor is reacted with a reactant to convert the adsorbed precursor to a film layer.

The term “processing chamber” generally represents an enclosure in which chemical and/or physical processes are performed on substrates. The pressure, substrate temperature and atmospheric composition within a processing chamber can be controllable to perform the chemical and/or physical processes.

The term “processing tool” may generally represent a machine comprising a processing chamber and other hardware configured to enable processing to be carried out in the processing chamber.

The term “processing station” generally represents a location in a processing chamber at which a substrate is positioned during processing.

The term “reactant” generally represents a chemical species that reacts with a precursor adsorbed to a substrate surface to form a film layer in an ALD process. A reaction between a reactant and a precursor can be facilitated by thermal energy and/or a plasma in various processes.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The work piece may be of various shapes, sizes, and materials. In addition to semiconductor wafers, other work pieces that may take advantage of the disclosed implementations include various articles such as printed circuit boards and the like.

The term “through-substrate via” generally represents an electrically conductive pathway in an integrated circuit that extends through a semiconductor substrate.

By “aliphatic” is meant a hydrocarbon moiety having at least one carbon atom to 50 carbon atoms (C₁₋₅₀), such as one to 25 carbon atoms (C₁₋₂₅), or one to ten carbon atoms (C₁₋₁₀), and which includes saturated groups such as alkanes (or alkyl) and unsaturated groups such as alkenes (or alkenyl), alkynes (or alkynyl), and also includes cyclic versions thereof, and further including straight- and branched-chain arrangements, and all stereo and position isomers as well. Such a hydrocarbon can be unsubstituted or substituted with one or more groups, such as halogens or groups described herein for an alkyl group.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl. Non-limiting unsubstituted alkenyl groups include C₂₋₈ alkenyl, C₂₋₆ alkenyl, C₂₋₅ alkenyl, C₂₋₄ alkenyl, or C₂₋₃ alkenyl. Exemplary, non-limiting alkenyl groups include vinyl or ethenyl (—CH═CH₂), 1-propenyl (—CH═CHCH₃), allyl or 2-propenyl (—CH₂—CH═CH₂), 1-butenyl (—CH═CHCH₂CH₃), 2-butenyl (—CH₂CH═CHCH₃), 3-butenyl (e.g. —CH₂CH₂CH═CH₂), 2-butenylidene (e.g., ═CH—CH═CHCH₃), and the like.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), n-propyl (n-Pr or nPr), isopropyl (i-Pr or iPr), cyclopropyl, n-butyl (n-Bu or nBu), isobutyl (i-Bu or iBu), s-butyl (s-Bu or sBu), t-butyl (t-Bu or tBu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 3-, 4-, 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15)N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₈ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₂, C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkylcarbonyl” is meant an alkyl group as previously defined appended to the parent molecular moiety through a carbonyl group. Exemplary, non-limiting alkylcarbonyl groups include methylcarbonyl, ethylcarbonyl, and isopropylcarbonyl among others.

The term “alkylsilyl”, as used herein, refers to SiR₃ group, wherein at least one R is an alkyl, and each R is independently selected from H and an alkyl. Alkylsilyls include mono, bis, and tris alkylsilyls. Examples of alkylsilyls include trimethylsilyl, dimethylsilyl, methylsilyl, triethylsilyl, diethylsilyl, and ethylsilyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl. Non-limiting unsubstituted alkynyl groups include C₂₋₈ alkynyl, C₂₋₆ alkynyl, C₂₋₅ alkynyl, C₂₋₄ alkynyl, or C₂₋₃ alkynyl. Exemplary, non-limiting alkynyl groups include ethynyl (—C≡CH), 1-propynyl (—C≡CCH₃), 2-propynyl or propargyl (—CH₂C≡CH), 1-butynyl (—C≡CCH₂CH₃), 2-butynyl (—CH₂C≡CCH₃), 3-butynyl (—CH₂CH₂C≡CH), and the like.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amido” is meant —N(R^{N1})C(O)—, where R^{N1} is H, optionally substituted alkyl, or optionally substituted aryl.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aminoalkyl” is meant an alkyl group, as defined herein, substituted by an amino group, as defined herein.

By “aminoaryl” is meant an aryl group, as defined herein, substituted by an amino group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “azido” is meant —N₃.

By “branched alkenyl” is meant an isomer of a straight chain alkenyl compound; one having alkyl groups bonded to the main carbon chain.

By “cyano” is meant —CN.

By “carbonyl” is meant a —C(O)— group, which can also be represented as >C═O.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “deposition” or “vapor deposition” is meant a process in which a metal layer is formed on one or more surfaces of a substrate from vaporized precursor composition(s) including one or more metal containing compounds. The metal-containing compounds are vaporized and directed to and/or contacted with one or more surfaces of a substrate (i.e., semiconductor substrate or semiconductor assembly) placed in a deposition chamber. Typically, the substrate is heated. These metal containing compounds form a non-volatile, thin, uniform metal-containing layer on the surface(s) of the substrate. One operation of the method is one cycle, and the process can be repeated for as many cycles necessary to obtain the desired metal thickness.

By “dicarbonyl” is meant any moiety or compound including two carbonyl groups, as defined herein. Non-limiting dicarbonyl moieties include 1,2-dicarbonyl (e.g., R^{C1}—C(O)—C(O)R^{C2}, in which each of R^{C1} and R^{C2} is, independently, optionally substituted alkyl, halo, optionally substituted alkoxy, hydroxyl, or a leaving group); 1,3-dicarbonyl (e.g., R^{C1}—C(O)—C(R^{1a}R^{2a})—C(O)R^{C2}, in which each of R^{C1} and R^{C2} is, independently, optionally substituted alkyl, halo, optionally substituted alkoxy, hydroxyl, or a leaving group and in which each of R^{1a} and R^{2a} is, independently, H or an optional substituent provided for alkyl, as defined herein); and 1,4-dicarbonyl (e.g., R^{C1}—C(O)—C(R^{1a}R^{2a})—C(R^{3a}R^{4a})—C(O)R^{C2}, in which each of R^{C1} and R^{C2} is, independently, optionally substituted alkyl, halo, optionally substituted alkoxy, hydroxyl, or a leaving group and in which each of R^{1a}, R^{2a}, R^{3a}, and R^{4a} is, independently, H or an optional substituent provided for alkyl, as defined herein).

The term “fluoroalkyl”, as used herein, refers alkyl groups containing one or more fluorine substituents. In some implementations fluoroalkyls contain exclusively fluorine substituents, such as in CF₃, C₂F₅, C₃F₇. Fluoroalkyls may be linear, branched and cyclic.

By “halo” is meant F, Cl, Br, or L.

By “halo containing substituent” is meant a group that contains a halo, such as a haloaliphatic or haloalkyl group.

By “haloaliphatic” is meant an aliphatic group, as defined herein, substituted with one or more halo.

By “haloalkenyl” is meant an alkenyl group, as defined herein, substituted with one or more halo.

By “haloalkynyl” is meant an alkynyl group, as defined herein, substituted with one or more halo.

By “haloalkyl” is meant an alkyl group, as defined herein, substituted with one or more halogen. Non-limiting unsubstituted haloalkyl groups include C₁₋₂ haloalkyl, C₁₋₃ haloalkyl, C₁₋₄ haloalkyl, C₁₋₅ haloalkyl, C₁₋₆ haloalkyl, C₂₋₃ haloalkyl, C₂₋₄ haloalkyl, C₂₋₅ haloalkyl, C₂₋₆ haloalkyl, or C₃₋₆ haloalkyl. Other non-limiting haloalkyl groups include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; —CH₂CX_{y}H_{3-y}, wherein y is 1, 2, or 3, and wherein each X is, independently, halo (F, Cl, Br, or I); —CX_{z1}H_{2-z1}CX_{z2}H_{2-z2}CX_{y}H_{3-y}, wherein each of z1 and z2 is, independently, 0, 1, or 2, wherein y is 0, 1, 2, or 3, and wherein each X is, independently, halo (F, Cl, Br, or I), in which at least one of z, z2, or y is not 0; and —CX_{z}H_{1-z}[CX_{y1}H_{3-y1}][CX_{y2}H_{3-y2}], wherein z is 0 or 1, wherein each of y1 and y2 is, independently, 0, 1, 2, or 3, and wherein each X is, independently, halo (F, Cl, Br, or I), in which at least one of z, y1, or y2 is not 0.

By “haloalkylene” is meant an alkylene group, as defined herein, substituted with one or more halo.

By “heterocyclyl” is meant a 3-, 4-, 5-, 6- or 7-membered ring, unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotrazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl, benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for aryl.

By “hydroxyl” is meant —OH.

By “imino” is meant —NR—, in which R can be H or optionally substituted alkyl.

By “isocyanato” is meant —NCO.

By “isocyano” is meant —N^{⊕}≡C^{⊖}—, and includes nitriles of the formula RN≡C—, wherein R is an aliphatic, aryl or heteroaryl group.

By “isothiocyanato” is meant —N═C═S.

By “low valent” is meant the lower oxidation states when a metal has multiple oxidation states.

By “oxo” is meant an ═O group.

By “oxy” is meant —O—.

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

Use of the above terms is meant to encompass substituted and unsubstituted moieties. Substitution may be by one or more groups such as alcohols, ethers, esters, amides, sulfones, sulfides, hydroxyl, nitro, cyano, carboxy, amines, heteroatoms, lower alkyl, lower alkoxy, lower alkoxycarbonyl, alkoxyalkoxy, acyloxy, halogens, trifluoromethoxy, trifluoromethyl, alkyl, aralkyl, alkenyl, alkynyl, aryl, cyano, carboxy, carboalkoxy, carboxyalkyl, cycloalkyl, cycloalkylalkyl, heterocyclyl, alkylheterocyclyl, heterocyclylalkyl, oxo, arylsulfonyl and aralkyaminocarbonyl, or any of the substituents of the preceding paragraphs or any of those substituents either directly attached or by suitable linkers. The linkers are typically short chains of 1-3 atoms containing any combination of —C—, —C(O)—, —NH—, —S—, —S(O)—, —O—, —C(O)— or —S(O)O—. Rings may be substituted multiple times.

The term “lower” modifying “alkyl”, “alkenyl”, “alkynyl”, “alkoxy” or “alkoxycarbonyl” refers to a C₁-C₆ unit for a particular functionality. For example, “lower alkyl” means C₁-C₆ alkyl.

By “substituted” is meant having one or more substituent moieties whose presence does not interfere with the desired function or reactivity. Examples of substituents alkyl, alkenyl, alkynyl, cycloalkyl (non-aromatic ring), Si(alkyl)₃, Si(alkoxy)₃, alkoxy, amino, alkylamino, alkenylamino, amide, amidine, guanidine, hydroxyl, thioether, alkylcarbonyl, alkylcaronyloxy, alkoxycarbonyloxy, carbonate, alkoxycarbonyl, aminocarbonyl, alkylthiocarbonyl, phosphate, phosphate ester, phosphonato, cyano, halo, acylamino, imino, sulfhydryl, alkylthio, thiocarboxylate, dithiocarboxylate, sulfate, sulfato, sulfonate, sulfamoyl, sulfonamide, nitro, nitrile, azido, heterocyclyl, ether, ester, silicon-containing moieties, thioester or a combination thereof. The substituents may themselves be substituted. For instance, an amino substituent may itself be mono or independently disubstituted by further substituents defined above, such as alkyl, alkenyl, alkynyl, and cycloalkyl (non-aromatic ring).

By “thiocyanato” is meant —SCN.

By “thioether” is meant to include to include both unidentate and multidentate (e.g. bidentate to tridentate) thioethers, as well as ligands that contain both thioether and thiolate (or other) moieties.

By “unsubstituted” is meant any open valence of an atom being occupied by hydrogen. Also, if an occupant of an open valence position on an atom is not specified, then it is hydrogen.

As used herein, the term “about” is understood to account for minor increases and/or decreases beyond a recited value, which changes do not significantly impact the desired function of the parameter beyond the recited value(s). In some cases, “about” encompasses+/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

The implementations disclosed below describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, LEDs, photovoltaic panels and the like.

By “unsaturated” is meant a moiety that contains double or triple carbon-carbon bonds.

By “unsaturated substituent” is meant a double or triple bond containing aliphatic chain, cyclic, aryl or heteroaryl group.

The term “independently selected”, when referring to R substituent selection in a molecule containing multiple R groups, means that the selection of R substituents at different atoms of a molecule is independent and that the selection of R substituents at one atom having multiple R substituents is also independent.

### Introduction & Context

Semiconductor manufacturing processes often involve deposition of dielectric materials including silicon-containing films. Such film may be used for gap fill in structures including 3D NAND structures, DRAM structures, and shallow trench isolation (STI) structures or onto patterned substrates to form conformal films for various applications, such as barrier layers for contacts. Silicon nitride and silicon carbide layers may be used as encapsulation films, spacers, and barrier films in advanced devices for logic and memory structures, such as FinFETs, MRAM, 3DXPoint, ReRAM, and PCRAM.

Embodiments described herein involve deposition by ALD. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form at least a partial layer of film. As an example, a silicon oxide deposition cycle may include the following operations: (i) delivery/adsorption of a silicon-containing precursor, (ii) purging of the silicon-containing precursor from the chamber, (iii) delivery of an oxygen-containing reactant with an optional plasma, and (iv) purging of the oxygen-containing reactant and/or plasma from the chamber. When a plasma is used during delivery of the second reactant, in some embodiments, this is referred to as plasma-enhanced atomic layer deposition (PEALD). Delivery or adsorption of the silicon-containing precursor may be referred to as a “dose” operation and delivery of the second reactant to react with the adsorbed precursor may be referred to as a “conversion” operation.

ALD processes use surface-mediated deposition reactions to deposit films on a layer-by-layer basis. In one example of an ALD process, a substrate surface that includes a population of surface-active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second reactant, such as an oxygen-containing reactant, is introduced to the chamber so that some of these molecules react with the first precursor adsorbed on the surface. In some processes, the second precursor reacts immediately with the adsorbed first precursor. In other embodiments, the second reactant reacts only after a source of activation is applied temporally. In some embodiments, a plasma is ignited during the second reactant dose. The chamber may then be evacuated again to remove unbound second reactant molecules. In some embodiments the chamber may not be completely evacuated. Additional ALD cycles may be used to build film thickness.

In some implementations, ALD methods may include plasma activation. However, in thermal ALD processes described herein, plasma is not ignited. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

As mentioned above, atomic layer deposition (ALD) can be used to deposit dielectric films. ALD is particularly well-suited for forming conformal films in high aspect ratio (HAR) features due to the layer-by-layer nature of ALD film growth. As one example of a HAR feature, a through-substrate via (TSV) can be lined with a dielectric layer using ALD.

However, as feature sizes continue to decrease in integrated circuits, crosstalk and charge buildup pose concerns. The use of dielectric materials with lower dielectric constants can help mitigate issues with crosstalk and charge buildup. One approach to lower the dielectric constant of a silicon oxide dielectric film is to dope the silicon oxide dielectric film with fluorine. However, traditional methods of forming halogen-doped dielectric films, such as fluorine-doped silicon oxide films, employ temperatures that can be unsuitably high for some semiconductor fabrication processes, such as damascene processes. Further, such methods can lack the capacity to form halogen-doped silicon oxide as a conformal film in HAR features.

A more recent method for forming a conformal dielectric film doped with a halogen is to use an ALD process in which ALD cycles and halogen doping steps are performed in an alternating matter. First, an ALD cycle is performed to deposit a layer of a dielectric film. Then, a halogen doping step is performed by exposing the layer of the dielectric film to a halogen-containing precursor in the presence of a plasma. Such a process can be used to form a conformal halogen-doped dielectric film in HAR features at temperatures suitably low for damascene processes. However, performing a plasma doping step after each ALD cycle increases the process time for forming the halogen-doped dielectric film compared to forming an undoped dielectric film. As such, the halogen doping steps can reduce throughput compared to the deposition of a dielectric film without halogen doping.

In some embodiments, the presently disclosed precursors are vehicles specifically designed for an FSG process which can deliver more than one dopant, in contrast to conventional techniques which require two different precursors to deliver more than one dopant.

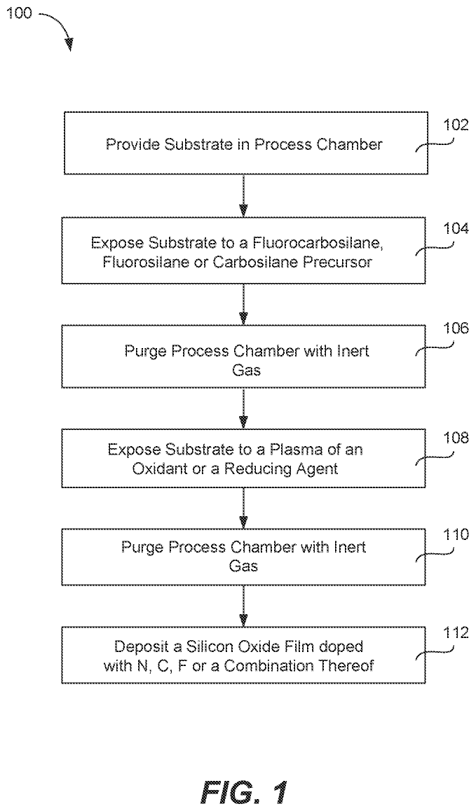

FIG. 1 presents a process flow diagram for a non-limiting method 100 for deposition of a doped silicon oxide film such as plasma-enhanced atomic layer deposition of a low dielectric constant doped silicon oxide film in accordance with certain disclosed embodiments.

Doped SiO₂ materials, commonly SiOC and SiOF have been employed in some applications as ILDs and IMDs, where the dopant source bond with Si replaces other more polarizable bonds such as Si—O or Si—OH, resulting in a lower dielectric constant film. However, processes which dope silicon oxide films with fluorine by plasma treatment may provide inconsistent in-feature fluorine conformality. In some instances, the fluorine concentration inside a feature may drop off as a function of depth due to typical plasma constraints. To resolve the issues with fluorine conformality in an FSG process, the methods of the present disclosure, such as method 100, utilize fluorine and/or carbon-containing silicon precursors which can survive the conditions of PEALD.

In operation 102, a substrate is provided to a process chamber. The substrate may be, for example, a hardmask, a film, a stack, a partially fabricated semiconductor device film stack, etc., fabricated in any suitable way. In some embodiments, the substrate may include a hardmask disposed on a work piece, such as the partially fabricated semiconductor device film stack. The hardmask, on the uppermost layer of the film stack, may have a variety of compositions, such as SiO₂, silicon nitride or an ashable hardmask material.

Yet other substrates can be employed. For instance, the substrate can be or include an amorphous hydrogenated carbon, silicon oxide, silicon nitride, silicon oxynitride, silicon carbide, silicon boronitride, amorphous silicon, polysilicon, or a combination of any described herein, in any form (e.g., a bulk film, a thin film, another film, a stack, etc.).

The substrate may be a silicon wafer, e.g., a 200-mm wafer, a 300-mm wafer, or a 450-mm wafer, including wafers having one or more layers of material, such as dielectric, conducting, or semi-conducting material deposited thereon. In various embodiments, the substrate is patterned. A patterned substrate may have “features” such as pillars, poles, trenches, via or contact holes, which may be characterized by one or more of narrow and/or re-entrant openings, constrictions within the feature, and high aspect ratios. One example of a feature is a hole or via in a semiconductor substrate or in a layer on the substrate. Another example is a trench in a substrate or layer. A further example of a feature is a pillar or pole in a semiconductor substrate or a layer on the substrate.

A feature typically has an aspect ratio (depth to lateral dimension). A feature having a high aspect ratio can have a depth to lateral dimension aspect ratio equal to or greater than about 10:1, equal to or greater than about 15:1, equal to or greater than about 20:1, equal to or greater than about 25:1, equal to or greater than about 30:1, equal to or greater than about 40:1, equal to or greater than about 50:1, or equal to or greater than about 100:1.

In various embodiments, the feature may have an under-layer, such as a barrier layer or adhesion layer. Non-limiting examples of under-layers include dielectric layers and conducting layers, e.g., silicon oxides, silicon nitrides, undoped silicon carbides, oxygen-doped silicon carbides, nitrogen-doped silicon carbides, metal oxides, metal nitrides, metal carbides, and metal layers.

The feature(s) may be formed in one or more of the above-described layers.

The methods described herein can be used to fill vertically oriented features formed in a substrate. Such features may be referred to as gaps, recessed features, negative features, unfilled features, or simply features. Filling such features may be referred to as gapfill.

In some embodiments, the feature(s) such as a pillar may have an aspect ratio of at least about 1:1, at least about 2:1, at least about 4:1, at least about 6:1, at least about 10:1, or higher. The feature(s) may also have a dimension near the opening, e.g., an opening diameter or line width of between about 10 nm to 500 nm, for example between about 25 nm and about 300 nm. Disclosed methods may be performed on substrates with feature(s) having an opening less than about 150 nm.

A via, trench or other recessed feature may be referred to as an unfilled feature or a feature. According to various embodiments, the feature profile may narrow gradually and/or include an overhang at the feature opening. A re-entrant profile is one that narrows from the bottom, closed end, or interior of the feature to the feature opening. A re-entrant profile may be generated by asymmetric etching kinetics during patterning and/or the overhang due to non-conformal film step coverage in the previous film deposition, such as deposition of a diffusion barrier.

Features of a substrate can be of various types. In some embodiments, a feature can have straight sidewalls, positively sloped sidewalls, or negatively sloped sidewalls. In some embodiments, a feature can have sidewall topography or sidewall roughness, which may occur as a result of an etch process to form the feature. In some embodiments, a feature can have a feature opening that is greater at the top of the feature than at the bottom, or a feature can have a feature opening that is greater at the bottom of the feature than at the top. In some embodiments, a feature can be partially filled with material or have one or more under-layers. Gapfill of features such as any of foregoing embodiments can depend on feature type and profile.

Examples of suitable process chambers include a parallel-plate type reactor, a cold wall type reactor, a hot wall type reactor, a single wafer reactor, a multi-wafer reactor, a direct plasma reactor or other types of deposition systems under conditions suitable to cause precursors to react and form layers. Such process chambers are described in greater detail in the Apparatus section below.

The substrate may be placed on a pedestal within the process chamber. The pedestal may be heated to a temperature of between about 50° C. to about 650° C. in certain embodiments.

Returning to FIG. 1, in operation 104 the substrate is exposed to a flurocarbosilane, fluorosilane or carbosilane precursor. Suitable precursors are described in the following paragraphs. Operation 104 may be performed at a temperature of from about 100° C. to about 400° C. in some embodiments. The precursor may be co-flowed with an inert gas such as argon at a flow rate of from about 1,500 to about 11,500 sccm.

In certain embodiments, the precursor may be treated by plasma in plasma doses in order to decompose the precursor into its radical form. Dose plasma may be utilized in order to tune doping concentration. The plasma may be generated or present within the processing chamber itself. Alternatively, the plasma may generally be at a location removed from the processing chamber, for instance, in a remotely located plasma system.

For example, the precursor may be introduced into a direct plasma reactor which generates a plasma in the reactor to produce the plasma treated precursor in the reactor. The reactant may be introduced and held in the processing chamber prior to plasma processing.

Alternatively, the plasma processing may occur simultaneously with the introduction of the reactant. In situ plasma is typically at 13.56 MHz RF capacitively coupled plasma that is generated between the showerhead and the substrate holder. The substrate or the showerhead may be the powered electrode depending on whether positive ion impact occurs.

Typical applied powers in in-situ plasma generators are from approximately 100 W to approximately 1000 W.

Plasma may also be generated remotely, wherein the plasma-treated precursor is produced outside of the processing chamber.

Operation 104 may be performed at a pressure of from about 0.5 to about 20 Torr, or from about 3 to about 9 Torr; with a QSM (quad station module) power of from about 0.5 to about 6.5 kW and an RF time of from about 0.05 to about 5 seconds. Precursor plasma carrier gases include, but are not limited to, Ar, He, N₂, O₂, N₂O, and CO₂.

### The Precursors

Precursors may be fluorocarbosilanes, fluorosilanes or carbosilanes. As used herein, the term “carbosilane” refers to any precursor including at least one carbon atom and at least one silicon atom; the term “fluorosilane” refers to any precursor including at least one fluorine atom and at least one silicon atom which may have a direct Si-F bond; an indirect Si-F bond (fluorine connected to silicon through a linker such as an optionally substituted alkyl, aryl, amino or heterocyclyl group); the term “fluorocarboaminosilane” refers to any precursor including at least one fluorine atom, at least one carbon atom, at least one nitrogen atom and at least one silicon atom and the term “fluorocarbosilane” refers to any precursor including at least one fluorine atom, at least one carbon atom and at least one silicon atom.

Suitable carbosilanes include, but are not limited to, fluorocarboaminosilanes, fluorocarbosilanes and carboaminosilanes. In some embodiments, the carbosilane may be octamethylcyclotetrasiloxane, tetravinylmethylcyclotetrasiloxane, tetramethylcyclotetrasiloxane, tetraethylorthosilicate, tetramethylorthosilicate, 1-dimethylamino-1,1,5,5,5,-pentamethyldisiloxane, 1-dimethylamino-1,1-dimethyldisiloxane, pentamethylcyclopentasiloxane or hexamethylcyclotrisiloxane.

Suitable fluorosilanes include, but are not limited to, bis-dimethylamino-difluoro-silane, bis-diethylamino-difluoro-silane, bis-diisopropylamino-difluoro-silane, bis-sec-butylamino-difluoro-silane, bis-t-butylamino-difluoro-silane, bis-trimethylsilylamino-difluoro-silane, tris-dimethylamino-fluoro-silane, tris-diethylamino-fluoro-silane, tris-diisopropylamino-fluoro-silane, and tris-sec-butylamino-fluoro-silane.

Suitable fluorocarbosilanes include, but are not limited to, bis-dimethylamino-bis-trifluoromethyl-silane, bis-diethylamino-bis-trifluoromethyl-silane, bis-diisopropylamino-bis-trifluoromethyl-silane, bis-sec-butylamino-bis-trifluoromethyl-silane, bis-t-butylamino-bis-trifluoromethyl-silane, bis-trimethylsilylamino-bis-trifluoromethyl-silane, tris-dimethylamino-trifluoromethyl-silane, tris-diethylamino-trifluoromethyl-silane, tris-diisopropylamino-trifluoromethyl-silane, tris-sec-butylamino-trifluoromethyl-silane, bis-dimethylamino-bis-pentafluoroethyl-silane, bis-diethylamino-bis-pentafluoroethyl-silane, bis-diisopropylamino-bis-pentafluoroethyl-silane, bis-sec-butylamino-bis-pentafluoroethyl-silane, bis-t-butylamino-bis-pentafluoroethyl-silane, bis-trimethylsilylamino-bis-pentafluoroethyl-silane, tris-dimethylamino-pentafluoroethyl-silane, tris-diethylamino-pentafluoroethyl-silane, tris-diisopropylamino-pentafluoroethyl-silane, tris-sec-butylamino-pentafluoroethyl-silane, bis-dimethylamino-trifluoromethyl-silane, bis-diethylamino-trifluoromethyl-silane, bis-diisopropylamino-trifluoromethyl-silane, bis-sec-butylamino-trifluoromethyl-silane, bis-t-butylamino-trifluoromethyl-silane, bis-trimethylsilylamino-trifluoromethyl-silane, bis-dimethylamino-pentafluoroethyl-silane, bis-diethylamino-pentafluoroethyl-silane, bis-diisopropylamino-pentafluoroethyl-silane, bis-sec-butylamino-pentafluoroethyl-silane, bis-t-butylamino-pentafluoroethyl-silane, and bis-trimethylsilylamino-pentafluoroethyl-silane.

The precursors having one or more preferred features (a direct Si-F bond, an indirect Si—F, bond, a direct Si—C bond or a combination thereof) that facilitate the formation of a low-K film include the following:
1) siloxanes of the formula (R₃Si)₂O, where each R is independently H, D, F, methyl, ethyl or propyl; preferably in which at least one R is F, methyl or ethyl, more preferably H₃SiOSiH₃, H₃CSiH₂SiH₂CH₃ and F₃SiOSiF₃. Siloxanes contain oxygen atoms and thus can be used without a separate source of oxygen.
2) (fluoroalkyl)fluorosiloxanes of the formula [((R_{f})_{3-x-y}R¹ₓF_{y})Si]₂O where R_{f} is a perfluoromethyl, perfluoroethyl or perfluoropropyl group, R¹ is H or D, x is 0 or 1, y is 1 or 2, and x+y=1 or 2, preferably in which R_{f} is a trifluoromethyl, more preferably F₃CSiF₂OSiF₂CF₃.
3) (fluoroalkyl)silanes of the formula (R_{f})₄₋ₐSiR¹ₐ where R_{f} is a perfluoromethyl, perfluoroethyl or perfluoropropyl group, R¹ is H or D, and a is 0, 1, 2, or 3, preferably in which R_{f} is trifluoromethyl, more preferably F₃CSiH₃; (alkyl)fluorosilanes of the formula R²_{4-b}SiF_{b} where R² is methyl, ethyl or propyl, and b is 1, 2, or 3, preferably in which R² is methyl or ethyl, more preferably CH₃SiF₃ and CH₃CH₂SiF₃.
4) (fluoroalkyl)fluorosilanes of the formula (R_{f})_{4-c-b}SiR¹_{c}F_{b} where R_{f} is a perfluoromethyl, perfluoroethyl or perfluoropropyl group, R¹ is H or D, c is 0, 1, or 2, b is 1, 2, or 3 and c+b=1, 2 or 3, preferably in which R_{f} is trifluoromethyl, more preferably F₃CSiF₃.
5) alkylsiloxysilanes of the formula (R₃SiO)_{4-b}SiR_{b} where each R is independently H, D, F, methyl, ethyl or propyl, and b is 1, 2 or 3, preferably in which each R is independently H, D, methyl or ethyl, more preferably (CH₃)₃SiOSiH₃.
6) alkoxysilanes of the formula (R²O)₄₋ₐSiR¹ₐ, where R² is methyl, ethyl or propyl, R¹ is H or D, and a is 0, 1, 2, or 3, preferably in which R² is methyl or ethyl, more preferably H₃COSiH₃.
7) alkylalkoxysilanes of the formula (R²O)_{4-c-b}SiR²_{b}R¹ where each R² is independently methyl, ethyl or propyl, R¹ is H or D, c is 0, 1, or 2, b is 1, 2, or 3, and c+b=1, 2 or 3, preferably in which R² is methyl or ethyl, more preferably H₃COSiH₂CH₃.
8) silylmethanes (H₃Si)₄₋ₐCR¹ₐ where R¹ is H or D, and a is 0, 1, 2, or 3, more preferably (H₃Si)₃CH and tetrasilylmethane (H₃Si)₄C.
9) alkoxysilylmethanes of the formula (R²O)_{4-c-b}(H₃Si)_{b}CR¹_{c} where R² is methyl, ethyl or propyl, R¹ is H or D, c is 0, 1, 2, b is 1, 2, or 3, and c+b=1, 2 or 3, preferably in which R² is methyl or ethyl, more preferably CH₃O(H₃Si)CH₂.
10) alkylalkoxysilylmethanes of the formula (R²O)_{4-x-y-z}R²_{z}(H₃Si)_{y}CR¹ₓ where each R² is independently methyl, ethyl or propyl, R¹ is H or D, x is 0 or 1, y is 1 or 2, z is 1 or 2, and x+y+z=2 or 3, preferably in which each R² is independently methyl or ethyl, more preferably (CH₃O(CH₃)₂(H₃Si)C and (CH₃O)(CH₃)(H₃Si)₂C.

In certain embodiments, the fluorosilane is an aminosilane. Examples of aminosilane precursors with a direct Si-F bond include: SiF₃NR₂, SiF₂(NR₂)₂, SiF(NR₂)₃, SiF₂HNR₂, H₂SiFNR₂, or HSi(F)(NR₂)₂; where R may be an alkyl or alkylsilyl group such as methyl, ethyl, i-propyl, n-propyl, i-butyl, n-butyl, t-butyl, sec-butyl, n-pentyl or trimethylsilyl. Further examples include fluorinated derivatives of bis(t-butylamino)silane such as H(F)Si(NHC(CH₃)₃ and F₂Si(NHC(CH₃)₃.

Examples of aminosilane precursors with an indirect Si-F bond include: Si(CF₃)₃NR₂, Si(CF₃)₂(NR₂)₂, Si(CF₃)(NR₂)₃, Si(CF₃)(NR₂)₃, HSi(CF₃)₂NR₂, H₂Si(CF₃)(NR₂), HSi(NR₂)₂(CF₃), Si(NR₂)(CF₂CF₃)₃, Si(NR₂)₂(CF₂CF₃)₂, Si(NR₂)₃(CF₂CF₃), HSi(NR₂)(CF₂CF₃)₂, H₂Si(NR₂)(CF₂CF₃), HSi(NR₂)₂(CF₂CF₃), Si(NR₂)(CFCF₂)₃, Si(NR₂)₂(CFCF₂)₂, Si(NR₂)(CFCF₂)₃, Si(NR₂)₃(CFCF₂), HSi(NR₂)(CFCF₂)₂, H₂Si(NR₂)(CFCF₂), or HSi(NR₂)₂(CFCF₂) where R may be an alkyl or alkylsilyl group such as methyl, ethyl, i-propyl, n-propyl, i-butyl, n-butyl, t-butyl, sec-butyl, n-pentyl or trimethylsilyl.

The silicon-containing precursor may have from one to five silicon atoms in certain embodiments, including silanes, disilanes and trisilanes. Examples include fluorinated derivatives of 1-dimethylamino-1,1,5,5,5-pentamethyldisiloxane; hexamethylcyclotrisiloxane, hexahydrocyclotrisiloxane, octamethylcyclotetrasiloxane, octahydrocyclotetrasiloxane, decahydrocyclopentasiloxane, decamethylcyclopentasiloxane, disiloxane and diisopropylaminosilane.

Optionally, the fluorosilane may have both direct Si-F bonds and indirect Si-F bonds, where silicon and fluorine are connected through a linking group. In some embodiments, the precursor is an interhalogen (also referred to as a mixed halogen), containing one or more fluorine atoms and one or more chlorine, bromine and/or iodine atoms.

In some embodiments, the silicon-containing precursor has a structure of formula (1)

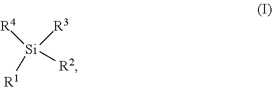

wherein R¹, R², R³ and R⁴ are each independently H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, heterocyclyl, amino, amido, hydrazino, azido, hydroxyl, halo, silyl, silyloxy, alkoxy, cyanato, isocyanato, isothiocyanato, thiocyanato, cyano, or isocyano; and wherein R¹ and R² may be linked to form a ring, or wherein R¹, R² and R³ may be linked to form a ring; and with the proviso that at least one of R¹, R², R³ and R⁴ is or includes fluorine, or that at least one of R¹, R², R³ and R⁴ includes carbon, or that at least one of R¹, R², R³ and R⁴ is or includes fluorine and at least one of R¹, R², R³ and R⁴ includes carbon.

In some embodiments, at least one of R¹, R², R³ and R⁴ is an optionally substituted haloaliphatic, haloalkyl, haloheteroaliphatic, halocyclic or haloaromatic group.

The precursor may have a structure of formula (II)

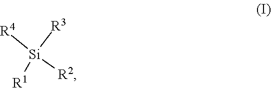

wherein: x is 1, 2, 3, or 4; each R′ is independently H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, heterocyclyl, aromatic, aromatic-carbonyl, aromatic-carbonyloxy, aromatic-oxy, aromatic-oxycarbonyl, heteroaromatic, heteroaromatic-oxy, amino, amido, hydrazino, azido, hydroxyl, halo, silyl, silyloxy, alkoxy, cyanato, isocyanato, isothiocyanato, thiocyanato, cyano, or isocyano; and each R″ is independently H, halo, aliphatic, heteroaliphatic, aromatic, heteroaromatic, alkylsilyl or amino; or optionally wherein two R″ can be taken together, with a nitrogen atom to which each is attached, to form an optionally substituted heterocyclyl; and with the proviso that at least one of R′ and R″ is or includes fluorine, or that at least one of R′ and R″ includes carbon, or that at least one of R′ and R″ is or includes fluorine and at least one of R′ and R″ includes carbon.

In some embodiments, at least one of R′ and R″ is an optionally substituted haloaliphatic, haloalkyl, haloheteroaliphatic, halocyclic or haloaromatic group. Each R′ may independently be hydrogen, —F, —CF₃, —CH₂CF₃, —CH₂CF₂, —CH₂CH₂F, —CHFCF₃, —CHFCHF₂, —CHFCH₂F, —C(F)═CF₂, —CF₂CF₃, —CF₂CH₃, —CF₂CHF₂, or —CF₂CH₂F in particular embodiments.

In the embodiment where two R″ can be taken together, with a nitrogen atom to which each is attached, to form an optionally substituted heterocyclyl, examples include structures of the formula (IIa) or (Ib)

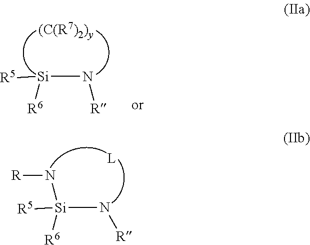

wherein each R″ is independently H, halo, aliphatic, heteroaliphatic, aromatic, heteroaromatic, alkylsilyl or amino; R³, R⁶ and R⁷ are each independently H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, halo, silyl, silyloxy, cyanato, isocyanato, cyano, or isocyano; L is ethylene, 1,2-cyclohexanediyl, benzyl-2-yl, o-phenylene or 1,8-naphthylene; and y is an integer of 3 or 4.

Another useful class of precursors includes disilanes. One example is a structure of formula (III)

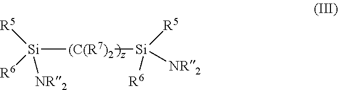

wherein each R″ is independently H, halo, aliphatic, heteroaliphatic, aromatic, heteroaromatic, alkylsilyl or amino; R⁵, R⁶ and R⁷ are each independently H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, heterocyclyl, aromatic, aromatic-carbonyl, aromatic-carbonyloxy, aromatic-oxy, aromatic-oxycarbonyl, heteroaromatic, heteroaromatic-oxy, amino, amido, hydrazino, azido, hydroxyl, halo, silyl, silyloxy, alkoxy, cyanato, isocyanato, istothiocyanato, thiocyanato, cyano, or isocyano; and z is an integer of 0 to 3; and with the proviso that at least one of R″, R⁵, R⁶ and R⁷ is or includes fluorine, or that at least one of R″, R⁵, R⁶ and R⁷ includes carbon, or that at least one of R″, R⁵, R⁶ and R⁷ is or includes fluorine and at least one of R″, R⁵, R⁶ and R⁷ includes carbon.

Exemplary fluoro carboaminosilane precursors include di-isopropylaminofluorosilane, 2,6-dimethylpiperidinofluorosilane, 2,6-dimethyl-piperidinodifluorosilane, di-sec-butylaminofluorosilane, di-sec-butylaminodifluorosilane, propylaminodifluorosilane, dicyclohexylaminofluorosilane, di-isobutylaminofluorosilane, di-isobutylaminodifluorosilane, cyclohexylmethylaminofluorosilane, cyclohexylaminofluorosilane, cyclohexyl-isopropylaminofluorosilane, cyclohexylmethylaminodifluorosilane, cyclohexylethylaminodifluorosilane, cyclohexyl-isopropylaminodifluorosilane, isopropylmethylaminofluorosilane, iso-propylethylaminofluorosilane, N-(fluorosilyl)perhydroquinoline, phenylmethylaminofluorosilane, phenylethylaminofluorosilane, phenyl-isopropylaminofluorosilane, phenylallylaminofluorosilane, m-tolylmethylaminofluorosilane, N-(fluorosilyl)-tetrahydroquinoline, N-fluorosilyl-3-anilinopropionitrile, N-fluorosilyl-Nphenylglycinonitrile, N-(fluorosilyl)carbazole, phenylcyclohexylaminofluorosilane, N-(fluorosilyl)-2-methylindoline, N-(fluorosilyl)benzomorpholine, N-(fluorosilyl)indole, N-(fluorosilyl)-2-methylindole, N-(fluorosilyl)-3-methylindoline, o-tolylethylaminofluorosilane, m-tolylethylaminofluorosilane, p-tolylmethylaminofluorosilane, o-tolylmethylaminofluorosilane and N-(fluorosilyl)-1,2,3,4-tetrahydro-2-methylquinoline.

Other useful precursors include, but are not limited to, fluorinated derivatives of trimethylamidosilane, bis(trimethylsilyl)amine, fluorinated silazanes (such as (F₃Si)₃N or ((CF₃)₃Si)N), silylborates, silylboranes, silylphosphates, silylphosphenes, silylenes, caged silanes, cyclopolysilane, cyclic or acyclic azesilanes, mixed alkoxyamidosilanes, silicon precursors having bidentate or tridentate ligands among others.

Returning to FIG. 1, the chamber housing the substrate being processed may be purged in operation 106 to remove precursors that are not adsorbed onto the substrate surface. Purging the chamber may involve flowing a purge gas or a sweep gas, which may be a carrier gas used in other operations or may be a different gas. Example purge gases include argon, nitrogen, hydrogen, and helium. In various embodiments, the purge gas is an inert gas. Example inert gases include argon, nitrogen, and helium. In some embodiments, purging may involve evacuating the chamber. In some embodiments, purging may include one or more evacuation subphases for evacuating the process chamber. Alternatively, it will be appreciated that purging may be omitted in some embodiments.

In operation 108, the substrate is exposed to a plasma of at least one oxidant gas or a plasma of at least one reducing agent. The plasma process conditions may be at a power between about 100 to about 500 W and a pressure of from about 2 to about 20 Torr. Example oxidants include oxygen (O₂), ozone (O₃), one or more oxides of nitrogen (e.g. nitrous oxide (N₂O)), water vapor (H₂O), hydrogen peroxide (H₂O₂) and combinations thereof. In some examples, a mixture of two or more different oxidants can be used. The oxidant or oxidants may be co-flowed with an inert gas in certain embodiments. Oxidant flow rates are typically between 500-5000 sccm, with the oxidant flow kept to the minimum required so as not to over-oxidize the film.

In some embodiments, the reducing agent can include hydrogen (H₂), ammonia (NH₃), carbon monoxide (CO), diborane (B₂H₆), sulfite compounds, carbon and/or hydrocarbons, phosphites, and/or hydrazine (N₂H₄). The reducing agent or reducing agents may be co-flowed with an inert gas in certain embodiments. Moreover, if a dose plasma is utilized to deliver the precursor, use of a reducing agent or an oxidant may be unnecessary in certain embodiments.

Subsequent to operation 108, the process chamber is purged again in operation 110 as described for operation 106 above.

Operation 112 is the deposition of an SiOC, SiOF, or SiOCF film, which may be doped with additional elements such as N, B, P, Sb, Ga or a combination thereof. Operations 104-112 represent a single PEALD cycle. The number of cycles is variable and depends upon the film thickness desired. The cycles may include repetitions with only oxidant, with only reductant or with alternation of oxidant and reductant after a particular number of cycles of each. A supercycle approach to deposition may also be utilized in which one or more cycles utilizes dose plasma, one or more subsequent cycles utilizes a reductant and one or more subsequent cycles utilizes an oxidant. An example process may be precursor/purge/reductant/purge×10/oxidant/purge.

Dopant percentages may range from about 0.01% to about 10% per element, depending upon the desired physical characteristics of the resulting film. Without wishing to be bound by theory, the use of an F- and/or C-containing silicon precursor is expected to improve dopant conformality through the use of self-limiting reactions. Additionally, the disclosed precursors may result in better F out-diffusion and decreased reactivity to moisture; and addition of C % to film may also cause wet etch to reduce, lowering it below that of thermal oxide.

### Apparatus

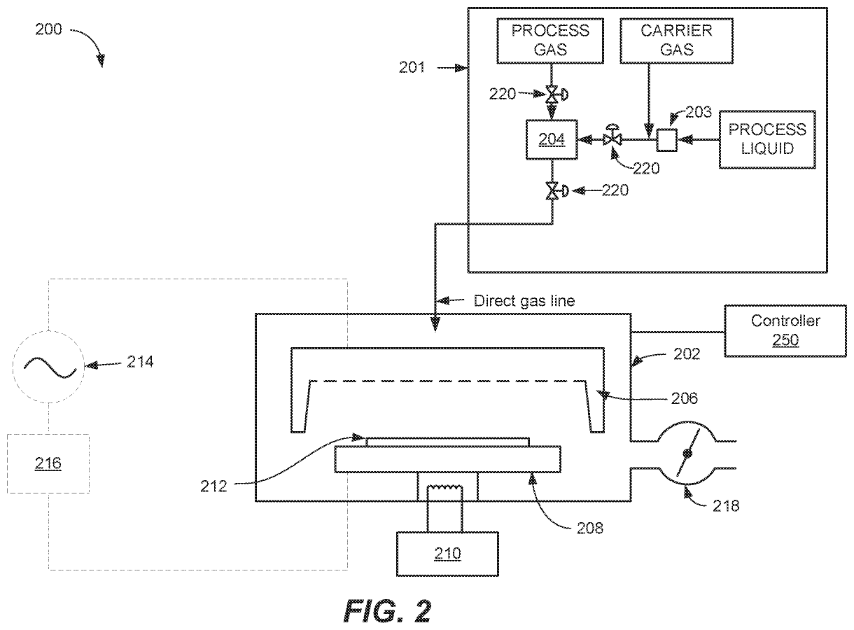

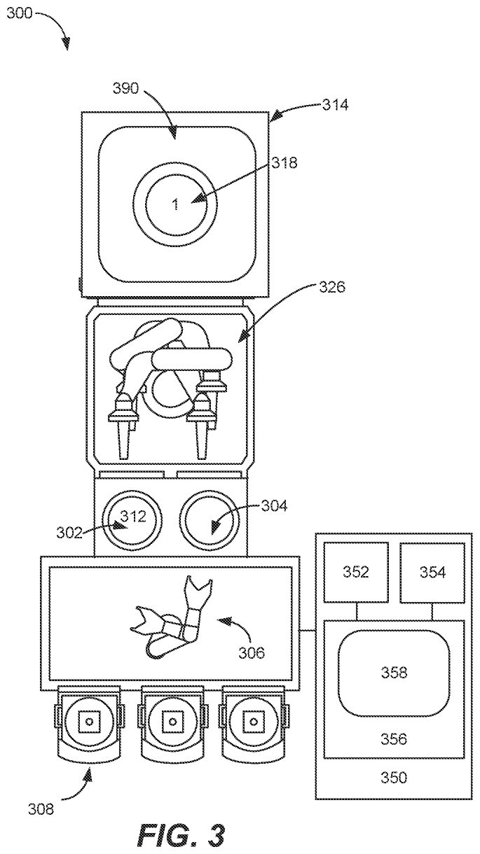

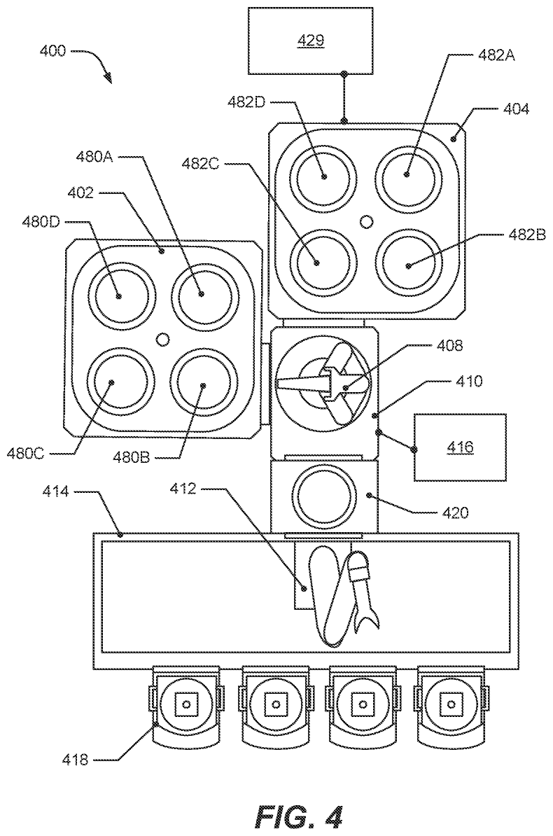

FIG. 2 depicts a schematic illustration of an embodiment of an atomic layer deposition (ALD) process station 200 having a process chamber body 202. In various embodiments, a single process station 200 is implemented in a tool such as shown in FIG. 3. In some embodiments, a plurality of ALD process stations 200 may be included in a low pressure process tool environment. For example, FIG. 4 depicts an embodiment of a multi-station processing tool 400. In some embodiments, one or more hardware parameters of ALD process station 200 including those discussed in detail below may be adjusted programmatically by one or more computer controllers 250.

ALD process station 200 fluidly communicates with reactant delivery system 201 for delivering process gases to a showerhead 206. Reactant delivery system 201 includes a mixing vessel 204 for blending and/or conditioning process gases, such as a silicon-containing precursor gas, or nitrogen-containing gas, for delivery to showerhead 206. One or more mixing vessel inlet valves 220 may control introduction of process gases to mixing vessel 204. One or more valves (not shown) may control introduction of gases to the showerhead 206.

As an example, the embodiment of FIG. 2 includes a vaporization point 203 for vaporizing liquid reactant to be supplied to the mixing vessel 204. In some embodiments, vaporization point 203 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 203 may be heat traced. In some examples, mixing vessel (not shown) may also be heat traced. In one non-limiting example, piping downstream of vaporization point 203 has an increasing temperature profile extending from approximately 40° C. to approximately 55° C. or from about 60° C. to about 65° C. at the mixing vessel.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 203. In one scenario, a liquid injector may be mounted directly to mixing vessel. In another scenario, a liquid injector may be mounted directly to showerhead 206.

In some embodiments, a liquid flow controller (LFC) upstream of vaporization point 203 may be provided for controlling a mass flow of liquid for vaporization and delivery to ALD process station 200. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 206 distributes process gases toward substrate 212. In the embodiment shown in FIG. 2, the substrate 212 is located beneath showerhead 206 and is shown resting on a pedestal 208. Showerhead 206 may have any suitable shape, and may have any suitable number and arrangement of ports for distributing process gases to substrate 212.

In some embodiments, pedestal 208 may be raised or lowered to expose substrate 212 to a volume between the substrate 212 and the showerhead 206. It will be appreciated that, in some embodiments, pedestal height may be adjusted programmatically by a suitable computer controller 250.

In another scenario, adjusting a height of pedestal 208 may allow a plasma density to be varied during plasma activation in the process in embodiments where a plasma is ignited. At the conclusion of the process phase, pedestal 208 may be lowered during another substrate transfer phase to allow removal of substrate 212 from pedestal 208.

In some embodiments, pedestal 208 may be temperature controlled via heater 210. In some embodiments, the pedestal 208 may be heated to a temperature of about 25° C. to about 800° C., or about 200° C. to about 700° C., during deposition of silicon oxide films as described in disclosed embodiments. In some embodiments, the pedestal is set at a temperature of about 45° C. to about 800° C., or about 500° C. to about 700° C. In some embodiments, the same pedestal 208 is used for multiple operations in accordance with certain disclosed embodiments.

Further, in some embodiments, pressure control for ALD process station 200 may be provided by butterfly valve 218. As shown in the embodiment of FIG. 2, butterfly valve 218 throttles a vacuum provided by a downstream vacuum pump (not shown). However, in some embodiments, pressure control of ALD process station 200 may also be adjusted by varying a flow rate of one or more gases introduced to the ALD process station 200.

In some embodiments, a position of showerhead 206 may be adjusted relative to pedestal 208 to vary a volume between the substrate 212 and the showerhead 206. Further, it will be appreciated that a vertical position of pedestal 208 and/or showerhead 206 may be varied by any suitable mechanism within the scope of the present disclosure. In some embodiments, pedestal 208 may include a rotational axis for rotating an orientation of substrate 212. It will be appreciated that, in some embodiments, one or more of these example adjustments may be performed programmatically by one or more suitable computer controllers 250.

In some embodiments where plasma may be used as discussed above, showerhead 206 and pedestal 208 electrically communicate with a radio frequency (RF) power supply 214 and matching network 216 for powering a plasma. For example, plasma may be used for treating a silicon oxide surface prior to depositing silicon nitride. In some embodiments, the plasma energy may be controlled by controlling one or more of a process station pressure, a gas concentration, an RF source power, an RF source frequency, and a plasma power pulse timing. For example, RF power supply 214 and matching network 216 may be operated at any suitable power to form a plasma having a desired composition of radical species. Examples of suitable powers are about 150 W to about 10000 W or about 500 W to about 6 kW for a single-station chamber. For a 3-station chamber, the plasma power may include four generators each powered up to about 10000 W, for a total of about 30000 W. For annealing a silicon oxide film, the substrate may be exposed to a nitrogen-containing gas, or a mixture of nitrogen-containing gases and optional inert gases while igniting a plasma using the RF power supply 214 and matching network 216.

In some embodiments, the substrate may be exposed to nitrogen-containing gas while igniting a plasma to anneal silicon oxide using plasma powers such as between about 500 W and about 10000 W per surface area of a 300 mm wafer. The plasma may be generated remotely (such as in a remote plasma generator) or directly in a chamber housing the substrate (i.e. in situ). RF power supply 214 may provide RF power of any suitable frequency. In some embodiments, RF power supply 214 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 3.45 GHz, or greater than about 13.56 MHz, or greater than 27 MHz, or greater than 30 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 250 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of a silicon-containing precursor gas, instructions for setting a flow rate of a carrier gas (such as argon), and time delay instructions for the first recipe phase. A second recipe phase may include modulating or stopping a flow rate of an inert and/or a reactant gas, instructions for optionally heating, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of a second silicon-containing precursor and time delay instructions for the third recipe phase. A fourth recipe phase may include instructions for modulating or stopping a flow rate of an inert and/or a reactant gas, instructions for modulating the flow rate of a carrier or purge gas, and time delay instructions for the fourth recipe phase. A fifth, subsequent recipe phase may include instructions for setting a flow rate of a nitrogen-containing gas, instructions for igniting a plasma, and instructions for modulating a flow rate of a carrier or purge gas and time delay instructions for the fifth recipe phase. A sixth recipe phase may include instructions for modulating or stopping a flow rate of an inert and/or a reactant gas, instructions for modulating the flow rate of a carrier or purge gas, and time delay instructions for the sixth recipe phase. It will be appreciated that these recipe phases may be further subdivided and/or iterated in any suitable way within the scope of the disclosed embodiments. In some embodiments, the controller 250 may include any of the features described below with respect to system controller 350 of FIG. 3 and system controller 450 of FIG. 4.

A process station may be included in a single-station chamber or single-chamber tool such as shown in FIG. 3. FIG. 3 depicts an example processing apparatus according to disclosed embodiments. Tool 300 includes a processing chamber 314 which includes a processing station 390 may process a wafer. The processing chamber 314 is configured to deposit silicon oxide, deposit silicon nitride, anneal substrates using thermal or plasma anneals, and the like.

Tool 300 also includes a wafer transfer unit configured to transport wafers within the tool 300. Additional features of tool 300 will be discussed in greater detail below, and various features are discussed here with respect to some of the described techniques. In the depicted illustration, the wafer transfer unit includes a first robotic arm unit 326 in a first wafer transfer module and a second robotic arm unit 306 in a second wafer transfer module that may be considered an equipment front end module (EFEM) configured to received containers for wafers, such as a front opening unified module (FOUP) 308. The first robotic arm unit 326 is configured to transport a wafer between the processing chamber 314 and the second robotic arm unit via module 304 which may hold multiple wafers such as shown in module 302 with substrate 312. The second robotic arm unit 306 is configured to transport the wafer between a FOUP and module 304, or from module 302 to FOUP. After a wafer has been prepared in the module 304, the wafer transfer unit is able to transfer the wafer to first processing chamber 314 for deposition and optional anneal in situ.

Similar to above, the first wafer transfer module may a vacuum transfer module (VTM). Airlock or module 304, also known as a loadlock, is shown and may be individually optimized to perform various fabrication processes. The tool 300 also includes a FOUP 308 that is configured to lower the pressure of the tool 300 to a vacuum or low pressure, e.g., between about 1 mTorr and about 10 Torr, and maintain the tool 300 at this pressure. This includes maintaining the processing chamber 314, and the first wafer transfer module at the vacuum or low pressure. The second wafer transfer module may be at a different pressure, such as atmospheric. As the wafer is transferred throughout the tool 300, it is therefore maintained at the vacuum or low pressure.

In a further example, a substrate is placed in one of the FOUPs 308 and the second robot arm unit 306, or front-end robot, transfers the substrate from the FOUP 318 to an aligner, which allows the substrate to be properly centered before it is etched, or deposited upon, or otherwise processed. After being aligned, the substrate is moved by the second robot arm unit 306 into the airlock module 304. Because airlock modules have the ability to match the environment between an ATM and a VTM, the substrate is able to move between the two pressure environments without being damaged. From the airlock module 304, the substrate is moved by the first robot arm unit 326 through the first wafer transfer module, or VTM, and into the processing chamber 314. In order to achieve this substrate movement, the first robot arm unit 326 uses end effectors on each of its arms.

FIG. 3 also depicts an embodiment of a system controller 350 employed to control process conditions and hardware states of process tool 300. System controller 350 may include one or more memory devices 356, one or more mass storage devices 354, and one or more processors 352. Processor 352 may include a CPU or computer, analog and/or digital input/output connections, stepper motor controller boards, etc. In some embodiments, system controller 350 includes machine-readable instructions 358 for performing operations such as those described above with respect to FIG. 2 and below with respect to FIG. 4.

As described above, one or more process stations may be included in a multi-station processing tool. FIG. 4 depicts an example processing apparatus according to disclosed embodiments. Tool 400 includes a first processing chamber 402 and a second processing chamber 404. The first processing chamber 402 includes a plurality of processing stations, four stations 480A-D, that each may process a wafer. The first processing chamber 402 is configured to perform plasma treatment operations on the wafers. The second processing chamber 404 is configured to perform deposition on the wafer and may be considered a deposition chamber. The second processing chamber 404 also includes a plurality of processing stations, four stations 482A-D, that each may process a wafer. The first and second processing chambers 402 and 404 may be considered multi-station processing chambers.

Tool 400 also includes a wafer transfer unit configured to transport one or more wafers within the tool 400. Additional features of tool 400 will be discussed in greater detail below, and various features are discussed here with respect to some of the described techniques. In the depicted illustration, the wafer transfer unit includes a first robotic arm unit 408 in a first wafer transfer module 410 and a second robotic arm unit 412 in a second wafer transfer module 414 that may be considered an equipment front end module (EFEM) configured to received containers for wafers, such as a front opening unified module (FOUP) 416. The first robotic arm unit 408 is configured to transport a wafer between the first processing chamber 402 and the second processing chamber 404, and between the second the second robotic arm unit 412. The second robotic arm unit 412 is configured to transport the wafer between a FOUP and the first robotic arm unit 408. After a wafer has been treated in the first processing chamber 402, the wafer transfer unit is able to transfer the wafer from the first processing chamber 402, to the second processing chamber 404 where one or more layers of encapsulation material may be deposited on one or more wafers.

Similar to above, the first wafer transfer module 410 may a vacuum transfer module (VTM). Airlock 420, also known as a loadlock or transfer module, is shown and may be individually optimized to perform various fabrication processes. The tool 400 also includes a FOUP 416 that is configured to lower the pressure of the tool 400 to a vacuum or low pressure, e.g., between about 1 mTorr and about 10 Torr, and maintain the tool 400 at this pressure. This includes maintaining the first and second processing chambers 402 and 404, and the first wafer transfer module 410 at the vacuum or low pressure. The second wafer transfer module 414 may be at a different pressure, such as atmospheric. As the wafer is transferred throughout the tool 400, it is therefore maintained at the vacuum or low pressure. For example, as the wafer is transferred from the first processing chamber 402, into the first wafer transfer module 410, and to the second processing chamber 404, the wafer is maintained at the vacuum or low pressure and not exposed to atmospheric pressure.

In a further example, a substrate is placed in one of the FOUPs 418 and the second robot arm unit 412, or front-end robot, transfers the substrate from the FOUP 418 to an aligner, which allows the substrate to be properly centered before it is etched, or deposited upon, or otherwise processed. After being aligned, the substrate is moved by the second robot arm unit 412 into the airlock 420. Because airlock modules have the ability to match the environment between an ATM and a VTM, the substrate is able to move between the two pressure environments without being damaged. From the airlock 420, the substrate is moved by the first robot arm unit 408 through the first wafer transfer module 410, or VTM 410, and into the first processing chamber 402. In order to achieve this substrate movement, the first robot arm unit 408 uses end effectors on each of its arms.

FIG. 4 also depicts an embodiment of a system controller 429 employed to control process conditions and hardware states of tool 400. System controller 429 may include one or more memory devices (not shown), one or more mass storage devices (not shown), and one or more processors (not shown). Processors may include a CPU or computer, analog, and/or digital input/output connections, stepper motor controller boards, etc.

In some embodiments, system controller 429 controls all of the activities of tool 400. System controller 429 executes system control software stored in mass storage device, loaded into memory device, and executed on processor. Alternatively, the control logic may be hard coded in the system controller 429. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software may include instructions for controlling the timing, mixture of gases, gas flow rates, chamber and/or station pressure, chamber and/or station temperature, wafer temperature, target power levels, RF power levels, substrate pedestal, chuck and/or susceptor position, and parameters of a particular process performed by tool 400. System control software may be configured in any suitable way. For example, various process tool component subroutines or control objects may be written to control operation of the process tool components used to carry out various process tool processes. System control software may be coded in any suitable computer readable programming language.

In some embodiments, system control software may include input/output control (IOC) sequencing instructions for controlling the various parameters described above. Other computer software and/or programs stored on mass storage device and/or memory device associated with system controller 429 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal and to control the spacing between the substrate and other parts of tool 400.

A process gas control program may include code for controlling gas composition (e.g., silicon-containing precursor gases, nitrogen-containing gases, carrier gases, inert gases, and/or purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium or nitrogen) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 529. The user interface may include a display screen, graphical software displays of the apparatus and/or process conditions, and user input devices such as pointing devices, keyboards, touch screens, microphones, etc.

In some embodiments, parameters adjusted by system controller 429 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 429 from various process tool sensors. The signals for controlling the process may be output on the analog and digital output connections of tool 400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 429 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 429 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 429.

In some implementations, the system controller 429 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 429, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 429 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 429 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 429, in some implementations, may be a part of or coupled to a computer that is integrated with, coupled to the system, otherwise networked to the system, or a combination thereof. For example, the system controller 429 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 429 receives instructions in the form of data, which specify parameters for each of the processing steps to be performed during one or more operations. It should be understood that the parameters may be specific to the type of process to be performed and the type of tool that the system controller 429 is configured to interface with or control. Thus as described above, the system controller 429 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 429 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

An appropriate apparatus for performing the methods disclosed herein is further discussed and described in U.S. patent application Ser. No. 13/084,399 (now U.S. Pat. No. 8,728,956), filed Apr. 11, 2011, and titled “PLASMA ACTIVATED CONFORMAL FILM DEPOSITION”; and Ser. No. 13/084,305, filed Apr. 11, 2011, and titled “SILICON NITRIDE FILMS AND METHODS,” each of which is incorporated herein in its entireties.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for deposition of a doped silicon oxide film, the method comprising:
(a) providing a substrate in a process chamber;
(b) exposing the substrate to a silicon-containing precursor, wherein the silicon-containing precursor comprises a fluorocarbosilane, fluorosilane, or a carbosilane, and wherein the silicon-containing precursor comprises one to five silicon atoms;
(c) purging the process chamber with an inert gas;
(d) exposing the substrate to a plasma of an oxidant or a plasma of a reducing agent;
(e) purging the process chamber with an inert gas; and
(f) depositing a doped silicon oxide film,
wherein the doped silicon oxide film comprises a film doped with N, C, F or a combination thereof;
wherein the method comprises one or more cycles of operations (a)-(f); and
wherein the doped silicon oxide film has a dielectric constant of about 3.9 or less.

2. The method of claim 1, wherein the fluorosilane comprises a fluoro carboaminosilane precursor or a fluoroaminosilane precursor.

3. The method of claim 1, wherein the fluorosilane comprises a direct silicon-fluorine bond, fluorine connected to silicon through a linker, or a direct silicon-fluorine bond and fluorine connected to silicon through a linker.

4. The method of claim 3, wherein the linker comprises alkyl, aryl, amino or heterocyclyl.

5. The method of claim 1, wherein the silicon-containing precursor is a halogenated precursor comprising at least one fluorine.

6. The method of claim 5, wherein the halogenated precursor further comprises one or more halogens comprising chlorine, bromine, iodine and combinations thereof.

7. The method of claim 1, wherein the carbosilane comprises a fluorocarboaminosilane precursor, a fluorocarbosilane precursor, or a carboaminosilane precursor.

8. The method of claim 1, wherein the carbosilane comprises octamethylcyclotetrasiloxane, tetravinylmethylcyclotetrasiloxane, tetramethylcyclotetrasiloxane, tetraethylorthosilicate, tetramethylorthosilicate, pentamethylcyclopentasiloxane or hexamethylcyclotrisiloxane.

9. The method of claim 1, wherein the doped silicon oxide film further comprises a film doped with B, P, Sb, Ga or a combination thereof.

10. The method of claim 1, wherein the oxidant comprises oxygen, water, nitrous oxide, carbon dioxide, ozone, hydrogen peroxide or a combination thereof.

11. The method of claim 1, wherein exposing the substrate to the oxidant comprises flowing the oxidant in an inert gas comprising argon, nitrogen, neon, krypton, helium or a combination thereof.

12. The method of claim 1, wherein purging is performed by delivering an inert gas comprising argon, nitrogen, neon, krypton, helium or a combination thereof.

13. A method for deposition of a doped silicon oxide film, the method comprising:
(a) providing a substrate in a process chamber;
(b) exposing the substrate to a silicon-containing precursor, wherein the silicon-containing precursor includes at least one Si—F bond, at least one Si—C bond, or at least one Si—C bond and at least one Si—F bond and wherein the silicon-containing precursor comprises one to five silicon atoms;
(c) purging the process chamber with an inert gas;
(d) exposing the substrate to a plasma of an oxidant or a plasma of a reducing agent;
(e) purging the process chamber with an inert gas; and
(f) depositing a doped silicon oxide film,
wherein the doped silicon oxide film comprises a film doped with C, F or a combination thereof;
wherein the method comprises one or more cycles of operations (a)-(f); and
wherein the doped silicon oxide film has a dielectric constant of about 3.9 or less.

14. The method of claim 13, wherein the silicon-containing precursor comprises a structure of formula (I) 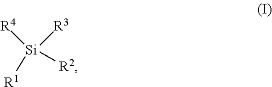
wherein R¹, R², R³ and R⁴ each independently comprise H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, heterocyclyl, amino, amido, hydrazino, azido, hydroxyl, halo, silyl, silyloxy, alkoxy, cyanato, isocyanato, isothiocyanato, thiocyanato, cyano, or isocyano; and
wherein R¹ and R² may be linked to form a ring, or wherein R¹, R² and R³ may be linked to form a ring; and
with the proviso that
at least one of R³, R², R³ and R⁴ is or comprises fluorine,
or that at least one of R¹, R², R³ and R⁴ comprises carbon,
or that at least one of R¹, R², R³ and R⁴ is or comprises fluorine and at least one of R¹, R², R³ and R⁴ comprises carbon.

15. The method of claim 14, at least one of R¹, R², R³ and R⁴ is haloaliphatic, haloalkyl, haloheteroaliphatic, halocyclic or haloaromatic.

16. The method of claim 13, wherein the silicon-containing precursor comprises a structure of formula (II) 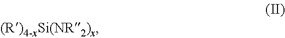
wherein:
x is 1, 2, 3, or 4;
each R′ independently comprises H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, heterocyclyl, amino, amido, hydrazino, azido, hydroxyl, halo, silyl, silyloxy, alkoxy, cyanato, isocyanato, isothiocyanato, thiocyanato, cyano, or isocyano; and
each R″ independently comprises H, halo, aliphatic, heteroaliphatic, aromatic, heteroaromatic, alkylsilyl or amino; or optionally wherein two R″ can be taken together, with a nitrogen atom to which each is attached, to form an optionally substituted heterocyclyl; and
with the proviso that
at least one of R′ and R″ is or comprises fluorine,
or that at least one of R′ and R″ comprises carbon,
or that at least one of R′ and R″ is or comprises fluorine and at least one of R′ and R″ comprises carbon.

17. The method of claim 16, wherein at least one of R′ and R″ is or comprises fluorine.

18. The method of claim 17, wherein at least one of R′ and R″ is haloaliphatic, haloalkyl, haloheteroaliphatic, halocyclic or haloaromatic.

19. The method of claim 17, wherein each R′ independently comprises hydrogen, —F, —CF₃, —CH₂CF₃, —CH₂CHF₂, —CH₂CH₂F, —CHFCF₃, —CHFCHF₂, —CHFCH₂F, —C(F)═CF₂, —CF₂CF₃, —CF₂CH₃, —CF₂CHF₂, or —CF₂CH₂F.

20. The method of claim 16, wherein two R″ can be taken together, with a nitrogen atom to which each is attached, to form an optionally substituted heterocyclyl of the formula (IIa) or (IIb) 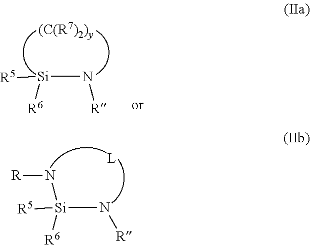
wherein each R″ independently comprises H, halo, aliphatic, heteroaliphatic, aromatic, heteroaromatic, alkylsilyl or amino;
R⁵, R⁶ and R⁷ each independently comprise H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, hydrazino, azido, hydroxyl, halo, silyl, silyloxy, cyanato, isocyanato, cyano, or isocyano;
L comprises ethylene, 1,2-cyclohexanediyl, benzyl-2-yl, o-phenylene or 1,8-naphthylene;
and y is an integer of 3 or 4.

21. The method of claim 13, wherein the silicon-containing precursor comprises a structure of formula (III) 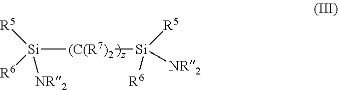
wherein each R″ independently comprises H, halo, aliphatic, heteroaliphatic, aromatic, heteroaromatic, alkylsilyl or amino;
R⁵, R⁶ and R⁷ each independently comprise H, aliphatic, aliphatic-carbonyl, aliphatic-carbonyloxy, aliphatic-oxy, aliphatic-oxycarbonyl, heteroaliphatic, heteroaliphatic-carbonyl, heteroaliphatic-carbonyloxy, heteroaliphatic-oxy, heteroaliphatic-oxycarbonyl, aromatic, aromatic-carbonyl, aromatic-carbonyloxy, aromatic-oxy, aromatic-oxycarbonyl, heteroaromatic, heteroaromatic-oxy, amino, amido, hydrazino, azido, hydroxyl, halo, silyl, silyloxy, alkoxy, heterocyclyl, cyanato, isothiocyanato, thiocyanato, isocyanato, cyano, or isocyano; and
z is an integer of 0 to 3; and
with the proviso that
at least one of R″, R⁵, R⁶ and R⁷ is or comprises fluorine,
or that at least one of R″, R⁵, R⁶ and R⁷ comprises carbon,
or that at least one of R″, R⁵, R⁶ and R⁷ is or comprises fluorine and at least one of R″, R⁵, R⁶ and R⁷ comprises carbon.

22. The method of claim 13, wherein the silicon-containing precursor is a halosilane, a carbosilane or a halocarbosilane.

23. The method of claim 13, wherein the doped silicon oxide film further comprises a film doped with N, B, P, Sb, Ga or a combination thereof.

24. The method of claim 13, wherein the oxidant comprises oxygen, water, nitrous oxide, carbon dioxide, ozone, hydrogen peroxide or a combination thereof.

25. The method of claim 13, wherein exposing the substrate to the oxidant comprises flowing the oxidant in an inert gas comprising argon, nitrogen, neon, helium, krypton or a combination thereof.

26. The method of claim 13, wherein purging is performed by delivering an inert gas comprising argon, nitrogen, neon, helium, krypton or a combination thereof.

27. An apparatus for deposition of a doped silicon oxide film, the apparatus comprising:
one or more process chambers comprising a substrate support;
a plasma generator;
one or more process gas sources connected with the process chamber and flow-control hardware; and
a controller having at least one processor and a memory, wherein
the at least one processor and the memory are communicatively connected with one another, the at least one processor is at least operatively connected with the flow-control hardware, and the memory stores computer-executable instructions for controlling the at least one processor to at least control the flow-control hardware to perform the method of claim 1.
